(19) United States
(12) Patent Application Publication
(10) Pub. No.: US 2013/0052768 A1
(43) Pub. Date: Feb. 28, 2013

(54) HIGH SPEED LASER SCANNING SYSTEM FOR SILICON SOLAR CELL FABRICATION

(71) Applicants: James M. Gee, Albuquerque, NM (US); Jeffrey L. Franklin, Albuquerque, NM (US)

(72) Inventors: James M. Gee, Albuquerque, NM (US); Jeffrey L. Franklin, Albuquerque, NM (US)

(73) Assignee: Applied Materials, Inc., Santa Clara, CA (US)

(21) Appl. No.: 13/589,922

(22) Filed: Aug. 20, 2012

Related U.S. Application Data
(60) Provisional application No. 61/527,080, filed on Aug. 24, 2011.

(51) Int. Cl. H01L 31/18

(52) U.S. Cl. 438/57; 250/453.11; 257/E31.11

(57) ABSTRACT

A laser scanning apparatus that uses a polygonal mirror and a beam shaper for laser drilling of holes in one or more layers during solar cell fabrication is provided. The apparatus may be used to laser drill holes in a back side passivation layer of a solar cell during back electrical contact formation. The apparatus includes the use of a polygonal mirror to improve the speed of the back electrical formation of a solar cell. The apparatus may also include the use of a beam shaper to tune the profile of the beam to prevent damage to the underlying solar cell substrate during laser drilling operations. A laser scanning module is provided which controls the speed and timing of linear movement of substrates and the operation of the laser scanning apparatus in a closed loop manner for laser drilling of material layers disposed on the substrates.

### CROSS-REFERENCE TO RELATED APPLICATIONS

This application claims benefit of U.S. provisional patent application Ser. No. 61/527,080, filed Aug. 24, 2011, which is incorporated herein by reference.

### BACKGROUND OF THE INVENTION

1. Field of the Invention

Embodiments of the present invention generally relate to an apparatus and method for laser drilling of holes in one or more layers during solar cell fabrication. In particular, the apparatus includes a polygonal mirror for improved laser drilling speed. In addition, the apparatus may include a beam shaper for preventing damage of an underlying solar cell substrate during drilling operations.

2. Description of the Related Art

Solar cells are photovoltaic devices that convert sunlight directly into electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost required to form solar cells.

One solar cell design in widespread use today has a p/n junction formed near the front surface, or surface that receives light, which generates electron/hole pairs as light energy is absorbed in the solar cell. This conventional design has a first set of electrical contacts on the front side of the solar cell, and a second set of electrical contacts on the back side of the solar cell. In order to form the second set of electrical contacts on the back side of the solar cell, holes must be formed in a passivation layer that covers the back side of a solar cell substrate to allow a conductive layer to contact the underlying solar cell substrate.

It is common to need in excess of 100,000 contact points (i.e., holes formed in the back side passivation layer) on a single solar cell substrate. Conventional approaches to forming holes in the back side passivation layer of the solar cell include the use of a galvanometer system to steer a laser beam across the solar cell substrate. However, these conventional systems are limited to rates of about 20 m/s. Thus, conventional approaches require significant time to produce conventional solar cells. In addition, using conventional laser systems, it is difficult prevent damage to the underlying solar cell substrate while drilling holes in the passivation layer.

Accordingly, improved methods and apparatus for drilling holes in a passivation layer of a solar cell substrate are needed.

### SUMMARY OF THE INVENTION

In one embodiment of the present invention, an apparatus for delivering electromagnetic radiation to a surface of a solar cell substrate comprises a polygonal mirror having a plurality of reflecting facets and an axis of rotation, an actuator configured to rotate the polygonal mirror relative to the axis of rotation, a laser source positioned to direct electromagnetic radiation to at least one of the reflecting facets of the polygonal mirror, and a substrate positioning device having a substrate supporting surface, wherein the substrate positioning device is configured to position a substrate to receive the electromagnetic radiation reflected from the reflecting facets of the polygonal mirror.

In another embodiment, a laser scanning module comprises a laser scanning device comprising a polygonal mirror and configured to scan pulses of electromagnetic radiation reflected by the polygonal mirror in a first direction across a surface of a substrate, a substrate positioning system configured to linearly transport the substrate in a second direction while the pulses of electromagnetic radiation are directed toward the substrate, wherein the second direction is substantially orthogonal to the first direction, one or more positioning sensors configured to detect a leading edge of the substrate as it is moved in the second direction toward the laser scanning device, and a system controller configured to control the operation of the laser scanning device and the substrate positioning system based on signals received from the one or more positioning sensors.

In yet another embodiment, a method of delivering electromagnetic radiation to a surface of a solar cell substrate comprises rotating a polygonal mirror having a plurality of reflecting faces about an axis of rotation, translating a substrate in a first direction, and delivering pulses of electromagnetic radiation to the plurality of reflecting faces as the polygonal mirror is rotated about the axis of rotation, wherein an amount of the delivered electromagnetic radiation is reflected from the plurality of reflecting faces toward a surface of the substrate, and wherein the reflected electromagnetic radiation is scanned across the surface of the substrate in a second direction that is orthogonal to the first direction.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a cross-sectional view of a solar cell that may be formed using apparatus and methods described herein.

FIG. 2 is a schematic, cross-sectional view of a laser scanning apparatus in accordance with embodiments described herein.

FIG. 3 is schematic, side view of a laser scanning module in accordance with embodiments described herein.

FIG. 4 is a schematic, top view of a substrate positioned on a substrate positioning system in accordance with embodiments described herein.

FIG. 5 is a schematic depiction of a laser scanning apparatus propagating a beam in accordance with embodiments described herein.

FIG. 6 is a schematic illustration of the Gaussian intensity profile of a beam without beam any beam shaping in accordance with embodiments described herein.

FIG. 7 is a schematic illustration of the intensity profile of the beam with beam shaping in accordance with embodiments described herein.

### DETAILED DESCRIPTION

Embodiments of the present invention provide a laser scanning apparatus that uses a polygonal mirror and a beam shaper for laser drilling of holes in one or more layers during solar cell fabrication. In one embodiment, the apparatus is used to laser drill holes in a back side passivation layer of a solar cell during back electrical contact formation. The apparatus includes the use of a polygonal mirror to improve the speed of the rear electrical contact formation of a solar cell. The apparatus may also include the use of a beam shaper to tune the profile of the beam to prevent damage to the underlying solar cell substrate during laser drilling operations. Further, a laser scanning module is provided which controls the speed and timing of linear movement of substrates and the operation of the laser scanning apparatus in a closed loop manner to provide efficient laser drilling of material layers disposed on the substrates.

As used herein, the term “laser drilling” generally means removal of at least a portion of material using laser processes. Thus, “laser drilling” may include ablation of at least a portion of a material layer disposed on a substrate, e.g., a hole through a material layer disposed on a substrate. Further, “laser drilling” may include removal of at least a portion of substrate material, e.g., forming a non-through hole (blind hole) in a substrate or a hole through a substrate.

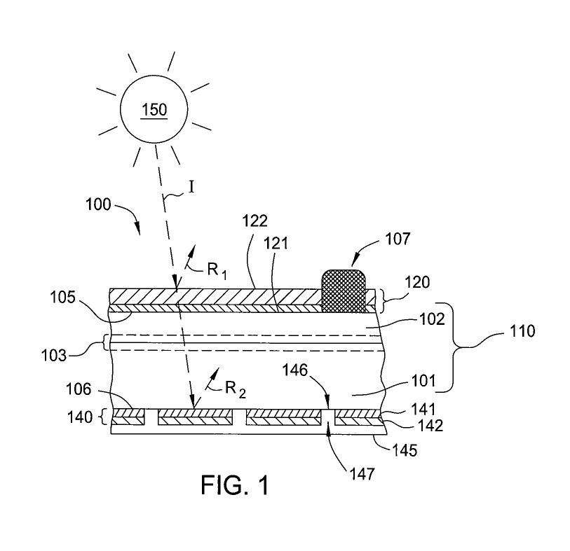

FIG. 1 illustrates a cross-sectional view of a solar cell 100 that may be formed using apparatus and methods described herein. The solar cell 100 includes a solar cell substrate 110 that has a passivation/ARC (anti-reflective coating) layer stack 120 on a front surface 105 of the solar cell substrate 110 and a rear passivation layer stack 140 on a rear surface 106 of the solar cell substrate.

In one embodiment, the solar cell substrate 110 is a silicon substrate that has a p-type dopant disposed therein to form part of the solar cell 100. In this configuration, the solar cell substrate 110 may have a p-type doped base region 101 and an n-doped emitter region 102 formed thereon. The solar cell substrate 110 also includes a p-n junction region 103 that is disposed between the base region 101 and the emitter region 102. Thus, the solar cell substrate 110 includes the region in which electron-hole pairs are generated when the solar cell 100 is illuminated by incident photons “I” from the sun 150.

The solar cell substrate 110 may include single crystal silicon, multicrystalline silicon, or polycrystalline silicon. Alternatively, the solar cell substrate 110 may include germanium (Ge), gallium arsenide (GaAs), cadmium telluride (CdTe), cadmium sulfide (CdS), copper indium gallium selenide (CIGS), copper indium selenide (CuInSe2), gallium indium phosphide (GaInP2), or organic materials. In another embodiment, the solar cell substrate may be a heterojunction cell, such as a GaInP/GaAs/Ge or a ZnSe/GaAs/Ge substrate.

In the example shown in FIG. 1, the solar cell 100 includes a passivation/ARC layer stack 120 and a rear passivation layer stack 140 that each contains at least two or more layers of deposited material. The passivation/ARC layer stack 120 includes a first layer 121 that is in contact with the front surface 105 of the solar cell substrate 110 and a second layer 122 that is disposed on the first layer 121. The first layer 121 and the second layer 122 may each include a silicon nitride (SiN) layer, which has a desirable quantity of trapped charge formed therein to effectively help bulk passivate the front surface 105 of the solar cell substrate.

In this configuration, the rear passivation layer stack 140 includes a first backside layer 141 that is in contact with the rear surface 106 of the solar cell substrate 110 and a second backside layer 142 that is dispose on the first backside layer 141. The first backside layer 141 may include an aluminum oxide (AlₓO_{y}) layer that is between about 200 Å and about 1300 Å thick and has a desirable quantity of trapped charge formed therein to effectively passivate the rear surface 106 of the solar cell substrate 110. The second backside layer 142 may include a silicon nitride (SiN) layer that is between about 600 Å and about 2500 Å thick. Both the first backside layer 141 and the second backside layer 142 have a desirable quantity of trapped charge formed therein to effectively help passivate the rear surface 106 of the substrate 110. The passivation/ARC layer stack 120 and the rear passivation layer stack 140 minimize front surface reflection R₁ and maximize rear surface reflection R₂ in the solar cell 100, as shown in FIG. 1, which improves efficiency of the solar cell 100.

The solar cell 100 further includes front side electrical contacts 107 extending through the passivation/ARC layer stack 120 and contacting the front surface 105 of the solar cell substrate 110. The solar cell 100 also includes a conductive layer 145 that forms rear side electrical contacts 146 that electrically contact the rear surface 106 of the solar cell substrate 110 through holes 147 formed in the rear passivation layer stack 140. The conductive layer 145 and the front side electrical contacts 107 may include a metal, such as aluminum (Al), silver (Ag), tin (Sn), cobalt (Co), nickel (Ni), zinc (Zn), lead (Pb), tungsten (W), titanium (Ti), tantalum (Ta), nickel vanadium (NiV), or other similar materials, and combinations thereof.

In forming the rear side electrical contacts 146, a number of through holes 147 must be formed in the rear passivation layer stack 140 without damaging the rear surface 106 of the solar cell substrate 110. In order to minimize the resistance losses in the solar cell 100 a high density of holes (e.g., between 0.5 and 5 holes per square millimeter) is required. For example, a 156 mm×156 mm solar cell may require up to 120,000 holes, which requires a significant amount of time using conventional laser drilling systems and processes, which are limited to about 20 m/s. Embodiments of the present invention provide an apparatus and method of more rapidly forming the holes 147 in the rear passivation layer stack 140 without damaging the rear surface 106 of the solar cell substrate 110.

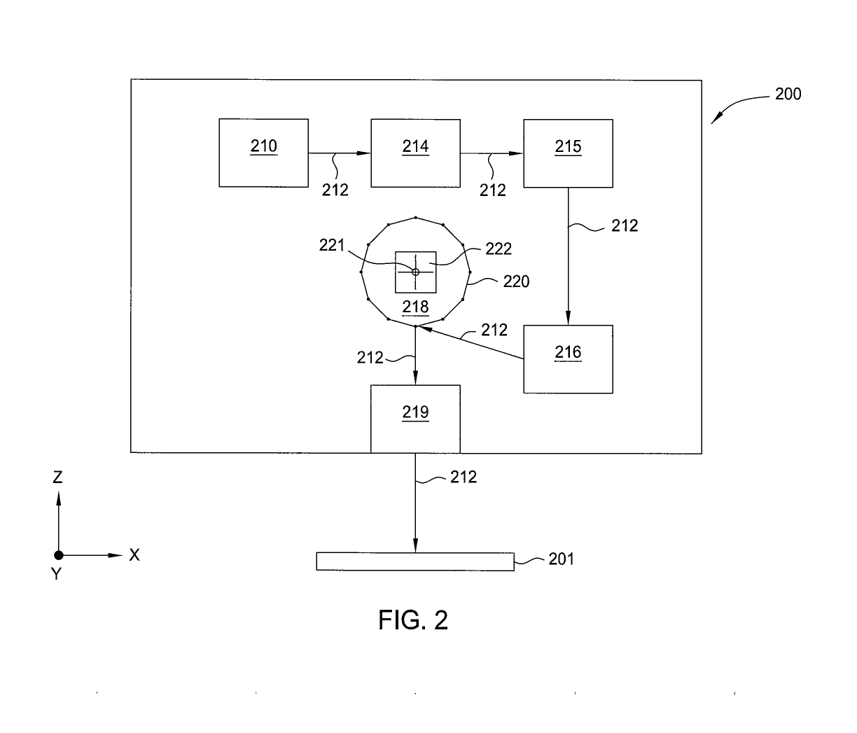

FIG. 2 is a cross-sectional view of a laser scanning apparatus 200 that may be used to form holes in one or more layers disposed on a substrate 201 in accordance with embodiments of the present invention. For example, the laser scanning apparatus 200 may be used to form the holes 147 in the rear passivation layer stack 140 of the solar cell 100 of FIG. 1.

In the embodiment shown in FIG. 2, the laser scanning apparatus 200 includes a laser source 210 that emits light or electromagnetic radiation 212 through a process of optical amplification based on stimulated emission of photons. The emitted electromagnetic radiation 212 has a high degree of spatial and temporal coherence. The laser source 210 may be a an electromagnetic radiation source such as a Nd:YAG, Nd:YVO₄, crystalline disk, fiber-Diode and other similar radiation emitting sources that can provide and emit a continuous wave of radiation at a wavelength between about 255 nm and about 1064 nm. In another embodiment, the laser source 210 includes multiple laser diodes, each of which produces uniform and spatially coherent light at the same wavelength. The power of the laser diodes may be in the range of about 5 W to about 15 W.

In one embodiment, the laser source 210 produces a pulse at a pulse width of from about 1 femtoseconds (fs) to about 1.5 microseconds (μs) having a total energy of from about 10 μJ/pulse to about 6 mJ/pulse. The pulse width and frequency of the pulses of electromagnetic radiation 212 may be controlled by use of a water cooled shutter. The laser pulse repetition rate may be between about 15 kHz and about 2 MHz.

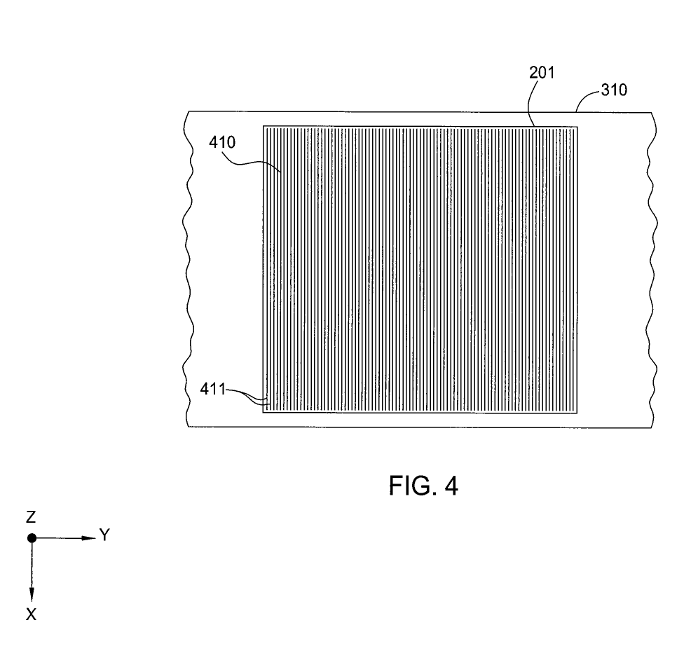

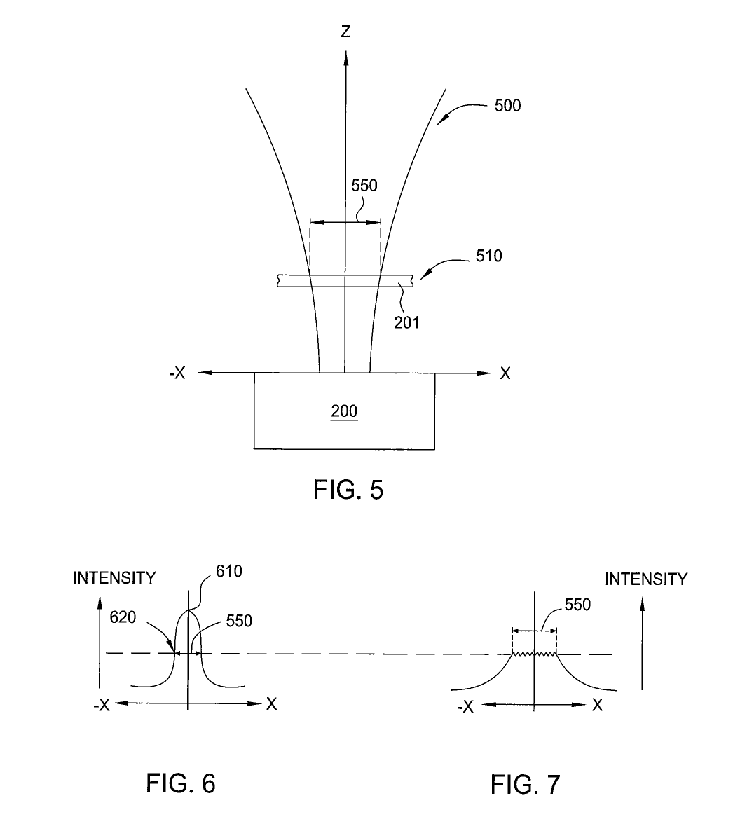

The pulses of electromagnetic radiation 212 emitted from the laser source 210 are received at a beam expander 214 having a first diameter, such as about 1.5 to about 2.5 mm. The beam expander 214 increases the diameter of the electromagnetic radiation 212 to a second diameter, such as between about 4 mm to about 6 mm. The pulses of electromagnetic radiation 212 are then delivered to a beam shaper 215 for tuning the shape of the beam as further described below with respect to FIGS. 5-7. From the beam shaper 215, the pulses of electromagnetic radiation 212 are delivered to a beam expander/focuser 216, which is used to adjust the diameter of the pulses of electromagnetic radiation 212 into a desired third diameter, such as between about 2 mm and about 3 mm.

The beam expander/focuser 216 then delivers the pulses of electromagnetic radiation 212 to a polygonal mirror 218, which reflects the pulses of electromagnetic radiation 212 through a focusing lens 219 and onto the substrate 201. The lens 219 may be a long focal length lens, such as a 254 mm lens. The polygonal mirror 218 is a mirror having multiple reflecting facets 220, such as between about 10 and 18, arranged such that each facet 220 is generally angled relative to each other in a direction relative to an axis of rotation 221 of the polygonal mirror 218. The angle of each of the reflecting facets 220 of the polygonal mirror 218 thus allows the electromagnetic radiation 212 to be scanned in one direction across the surface of the substrate 201 as the polygonal mirror 218 is rotated about the axis 221 by an actuator 222, such as an electric motor. The actuator 22 is used to control the speed of rotation of the polygonal mirror to a desired speed, such as a speed between about 100 and 10,000 rpm.

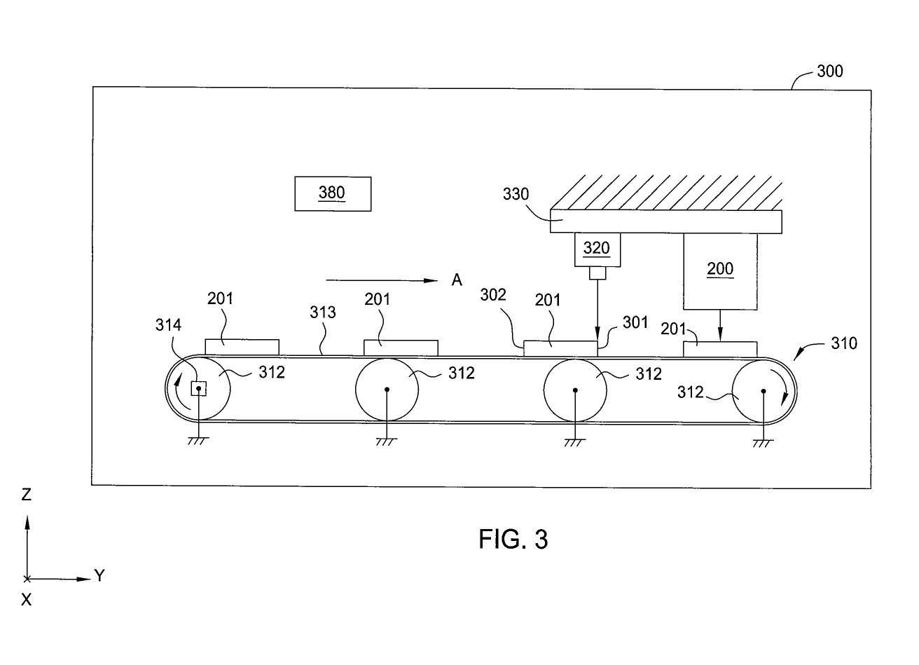

During processing, for example, as shown in FIG. 2, as the polygonal mirror 218 rotates about the axis 221, the pulses of electromagnetic radiation 212 are scanned across the substrate 201 to create a row of holes in one or more layers formed on the substrate 201, such as holes 147 in the rear passivation layer stack 140 from FIG. 1. In one embodiment, the rotation of a single facet 220, as it is reflecting the delivered pulses of electromagnetic radiation 212 from the laser source 210, creates a full row of holes (i.e., a row in the X-direction) in one or more layers formed on the substrate 201. As further described with respect to FIG. 3, the electromagnetic radiation 212 may be scanned across the surface of the substrate 201 by use of the rotating polygonal mirror 218, while the substrate 201 is transferred in an orthogonally oriented Y-direction resulting in rows of holes (i.e., in the X-direction) spanning the length of the substrate 201 (i.e., in the Y-direction). In some embodiments, the delivered pulses of electromagnetic radiation 212 are delivered to the substrate 201 in an overlapping fashion such that lines are formed through one or more layers of the substrate 201 rather than distinct holes.

FIG. 3 is schematic side view of a laser scanning module 300 for scanning rows of holes in one or more layers of the substrate 201 in accordance with embodiments of the present invention. The laser scanning module 300 includes a substrate positioning system 310, one or more substrate position sensors 320, the laser scanning apparatus 200, and a system controller 380.

The system controller 380 is adapted to control the various components of the laser scanning module 300. The system controller 380 generally includes a central processing unit (CPU) (not shown), memory (not shown), and support circuits (not shown). The CPU may be one of any form of computer processor used in industrial settings for controlling system hardware and processes. The memory is connected to the CPU and may be one or more of a readily available memory, such as random access memory (RAM), read only memory (ROM), floppy disk, hard disk, or any other form of digital storage, local or remote. Software instructions and data can be coded and stored within the memory for instruction the CPU. The support circuits are also connected to the CPU for supporting the processor in a conventional manner. The support circuits may include cache, power supplies, clock circuits, input/output circuitry subsystems, and the like. A program (instructions) readable by the system controller 380 includes code to perform tasks relating to monitoring, executing, and controlling the movement, support, and positioning of the substrates 201 along with various process recipe tasks to be performed in the laser scanning module 300. Thus, the system controller 380 is used to control the functions of the substrate positioning system 310, the one or more substrate position sensors 320, and the laser scanning apparatus 200.

In one embodiment, the substrate positioning system 310 is a linear conveyor system that includes support rollers 312, that support and drive a continuous transport belt 313 of material configured to support and transport a line of the substrates 201 through the laser scanning module 300. The rollers 312 may be driven by a mechanical drive 314, such as a motor/chain drive, and may be configured to transport the transport belt 313 at a linear speed of between about 100 and about 300 mm/s. The mechanical drive 314 may be an electric motor (e.g., AC or DC servo motor). The transport belt 313 may be made of a polymeric, stainless steel, or aluminum.

The substrate positioning system 310 is configured to sequentially transport a line of the substrates 201 (i.e., in the Y-direction) beneath a gantry 330, which supports the one or more position sensors 320 and the laser scanning apparatus 200. The one or more position sensors 320 are configured and positioned to detect a leading edge 301 of the substrate 201 as it is transported by the substrate positioning system 310 and send corresponding signals to the system controller 380. The signals from the one or more position sensors 320 are used by the system controller to determine and coordinate the timing of the delivery of the electromagnetic radiation 212 from the scanning apparatus 200.

For example, as the substrate 201 is transported by the substrate positioning system 310 along the flow path “A”, the one or more positioning sensors 320 detects the leading edge 301 of the substrate 201 and sends corresponding signals to the system controller 380. The system controller 380, in turn, sends signals to the laser scanning apparatus 200 to time the operation of the laser source 210 and the rotation of the polygonal mirror 218 to start the laser scanning operation as the leading edge of the substrate 201 is beneath the focusing lens 219 of the laser scanning apparatus 200. The system controller 380 further controls the rotational speed of the polygonal mirror 218 to scan a row of holes in one or more layers disposed on the substrate 201 (e.g., holes 147 in rear passivation layer stack 140 in FIG. 1) as each facet 220 is rotated across the pulses of electromagnetic radiation 212 (FIG. 2). The system controller 380 further controls the speed of the substrate positioning system 310 and the rotation of the polygonal mirror 218, such that as a first row of holes (e.g., aligned in the X-direction) is finished, the next row of holes begins as a desired spacing (e.g., Y-direction) from the first row due to the linear movement of the substrate 201 by the substrate positioning system 310. Accordingly, as the entire substrate 201 is moved beneath the laser scanning apparatus 200, rows of holes are formed in one or more layers of the substrate 201 across the entire width and length of the substrate 201 as shown and described below with respect to FIG. 4. The system controller 380 further controls the timing of the laser scanning apparatus 200, such that as the trailing edge 302 of the substrate 201 passes beneath the focusing lens 219, the scanning operation ceases until the leading edge of the next substrate 201 is positioned beneath the focusing lens 219. Failure to control the timing of the delivery of the electromagnetic radiation 212 will cause damage to one or more of the laser scanning module 300 components, such as the substrate positioning system 310.

As described above, the system controller 380 is used to control the functions and timing of the substrate positioning system 310 and the laser scanning apparatus 200 using closed loop feedback from the one or more positioning sensors 320. By controlling the speed of the linear movement of the substrate positioning system 310 and the optics in the laser scanning apparatus 200, the laser scanning module 300 can achieve laser drilling rates that far exceed that of conventional approaches. For example, through the use of the polygonal mirror configuration of the laser scanning apparatus 200 and the above-described control scheme, drilling rates of between about 60 m/s and about 200 m/s may be achieved. In comparison, conventional galvanometer systems are typically limited to less than 20 m/s. In addition, the use of the beam shaper 215 of the laser scanning apparatus 200 allows holes 147 to be efficiently drilled in the passivation layer stack 140 at such rates without damage to the underlying solar cell substrate 110 as further described with respect to FIGS. 5-7.

FIG. 4 is a schematic, top view of the substrate 201 positioned on the substrate positioning system 310 for use in performing a laser drilling process according to one embodiment. In one embodiment, the substrate 201 is a 156 mm×156 mm solar cell substrate, such as the solar cell substrate 110 with the rear surface 106, with the rear passivation layer stack 140 disposed thereon, facing upward.

As shown in FIG. 4, the laser scanning module 300 is used to form an array 410 of holes that are aligned in a line type pattern 411 via the laser drilling operations described above with respect to FIG. 3. In one example, each of the holes, in the array 410 of holes, may be formed through the passivation layer stack 140 and have a diameter of between about 40 and 70 μm without damaging the underlying material of the solar cell substrate 110 (e.g., monocrystalline silicon, poly-crystalline silicon). In one example, the holes have a diameter of between about 40 and 70 μm, are equally spaced from each other, and are formed by a single pass beneath the laser scanning apparatus 200 on the substrate positioning system 310.

As previously described, the removal of portions of material layers (e.g., laser drilling of holes 147 in the passivation layer stack 140 in FIG. 1) may be achieved with the laser scanning apparatus 200. Typically, the material ablation is conducted by pulsing the laser source 210 at a specific frequency, wavelength, pulse duration, and fluence at a specific spot on the substrate 201 to achieve complete evaporation or ablation of the irradiated material layer. However, it is difficult to achieve complete evaporation of a portion of a material layer, particularly the passivation layer stack 140, without damaging the underlying solar cell substrate 110.

One reason for the difficulty in removing a portion of the passivation layer stack 140 without damaging the solar cell substrate 110 is due to the variation in intensity across the area of the laser spot being focused on the substrate 201. In an ideal laser that emits a beam with a pure Gaussian profile, the peak intensity at the center of a desired spot on the material to be removed is higher than around the periphery of the spot (FIG. 6).

FIG. 5 is a schematic depiction of the laser scanning apparatus 200 propagating a beam 500 along a distance Z from the laser scanning apparatus 200. FIG. 6 is a schematic illustration of the Gaussian intensity profile of the beam 500 at the point 510 in FIG. 10 (i.e., without any beam shaping). The point 510 on the beam 500 represents a typical positioning of the substrate 201 with respect to the laser scanning apparatus 200, in order to achieve complete evaporation of the passivation layer stack 140 across a desired spot 550. As can be seen, the peak intensity 610 at the center of the spot 550 is significantly higher than the peripheral intensity 620 at the periphery of the spot 550 because the periphery of the spot 550 must be set at the ablation threshold of the material of the passivation layer stack 140. Thus, although the peripheral intensity 620 is just high enough to achieve ablation of the passivation layer stack 140 along the periphery of the spot 550, the significantly high peak intensity 610 causes damage to the underlying solar cell substrate 110 at the center of the spot 550 without any beam shaping.

In order to achieve complete ablation of the spot 550 in the passivation layer stack 140 without damaging the solar cell substrate 110, the beam shaper 215 is used. The beam shaper 215 may be a refractive beam shaper that converts a Gaussian laser beam into a collimated flat top beam. FIG. 7 is a schematic illustration of the intensity profile of the beam 500 at the point 510 in FIG. 5 with beam shaping. As can be seen, the beam shaping or “flat topping” operation results in a beam intensity profile having a uniform energy density just at the ablation threshold of the material in the passivation layer stack 140 across the entire area of the spot 550. Thus, use of the beam shaper 215 in the laser scanning apparatus 200 allows for efficient drilling of holes 147 in the passivation layer stack 140 without damaging the underlying solar cell substrate 110.

Thus, embodiments of the present invention provide a laser scanning apparatus that uses a polygonal mirror and a beam shaper for laser drilling of holes in one or more layers during solar cell fabrication. In one embodiment, the apparatus is used to laser drill holes in a back side passivation layer of a solar cell during rear electrical contact formation. The apparatus includes the use of a polygonal mirror to improve the speed of the back electrical contact formation of a solar cell. The apparatus may also include the use of a beam shaper to tune the profile of the beam to prevent damage to the underlying solar cell substrate during laser drilling operations. Further, a laser scanning module is provided which controls the speed and timing of linear movement of substrates and the operation of the laser scanning apparatus in a closed loop manner to provide efficient laser drilling of material layers disposed on the substrates.

While the foregoing is directed to embodiments of the present invention, other and further embodiments of the invention may be devised without departing from the basic scope thereof, and the scope thereof is determined by the claims that follow.

1. An apparatus for delivering electromagnetic radiation to a surface of a solar cell substrate, comprising:
a polygonal mirror having a plurality of reflecting facets and an axis of rotation;
an actuator configured to rotate the polygonal mirror relative to the axis of rotation;
a laser source positioned to direct electromagnetic radiation to at least one of the reflecting facets of the polygonal mirror; and
a substrate positioning device having a substrate supporting surface, wherein the substrate positioning device is configured to position a substrate to receive the electromagnetic radiation reflected from the reflecting facets of the polygonal mirror.

2. The apparatus of claim 1, wherein the substrate positioning device is configured to linearly transport the substrate while the electromagnetic radiation reflected from the reflecting facets is directed at the substrate.

3. The apparatus of claim 1, further comprising:
one or more positioning sensors; and
a system controller configured to receive signals from the one or more positioning sensors.

4. The apparatus of claim 3, wherein the one or more positioning sensors are configured to detect a leading edge of the substrate as the substrate positioning device linearly transports the substrate in a direction substantially orthogonal to the direction of the electromagnetic radiation reflected from the reflecting facets of the polygonal mirror.

5. The apparatus of claim 4, wherein the system controller is configured to control the operation of the laser source, the motor, and the substrate positioning system based on signals received from the one or more positioning sensors.

6. The apparatus of claim 1, further comprising a beam shaper positioned between the laser source and the polygonal mirror.

7. A laser scanning module, comprising:
a laser scanning device comprising a polygonal mirror and configured to scan pulses of electromagnetic radiation reflected by the polygonal mirror in a first direction across a surface of a substrate;
a substrate positioning system configured to linearly transport the substrate in a second direction while the pulses of electromagnetic radiation are directed toward the substrate, wherein the second direction is substantially orthogonal to the first direction;
one or more positioning sensors configured to detect a leading edge of the substrate as it is moved in the second direction toward the laser scanning device; and
a system controller configured to control the operation of the laser scanning device and the substrate positioning system based on signals received from the one or more positioning sensors.

8. The module of claim 7, wherein the laser scanning device further comprises:
a laser source; and
a beam shaper positioned between the laser source and the polygonal mirror.

9. The module of claim 8, wherein the laser scanning device further comprising an actuator configured to rotate the polygonal mirror at a desired speed.

10. A method of delivering electromagnetic radiation to a surface of a solar cell substrate, comprising:
rotating a polygonal mirror having a plurality of reflecting faces about an axis of rotation;
translating a substrate in a first direction; and
delivering pulses of electromagnetic radiation to the plurality of reflecting faces as the polygonal mirror is rotated about the axis of rotation, wherein an amount of the delivered electromagnetic radiation is reflected from the plurality of reflecting faces toward a surface of the substrate, and wherein the reflected electromagnetic radiation is scanned across the surface of the substrate in a second direction that is orthogonal to the first direction.

11. The method of claim 10, wherein the surface of the substrate has one or more material layers disposed thereon, and wherein a portion of each of the one or more layers is ablated as the reflected electromagnetic radiation is scanned across the surface of the substrate.

12. The method of claim 11, wherein a row of holes are formed through the one or more layers as the reflected electromagnetic radiation is scanned across the surface of the substrate.

13. The method of claim 11, wherein a plurality of rows of holes are formed through the one or more layers as the reflected electromagnetic radiation is scanned across the surface of the substrate.

14. The method of claim 11, wherein the position of the substrate as it is translated in the first direction is used to control the delivering the pulses of electromagnetic radiation.

15. The method of claim 11, wherein a plurality of holes are formed through the one or more layers as the reflected electromagnetic radiation is scanned across the surface of the substrate without damaging the surface of the substrate.

16. The method of claim 11, wherein the one or more layers comprises an aluminum oxide layer.

17. The method of claim 16, wherein the one or more layers further comprises a silicon nitride layer disposed on the aluminum oxide layer.

18. The method of claim 11, wherein the substrate is translated at a speed between about 100 and 300 mm/s.
